(19) United States
(12) Patent Application Publication
(10) Pub. No.: US 2014/0097542 A1
(43) Pub. Date: Apr. 10, 2014

(54) FLIP PACKAGING DEVICE

(71) Applicant: Silergy Semiconductor Technology (Hangzhou) LTD, Hangzhou (CN)

(72) Inventor: Xiaochun Tan, Hangzhou (CN)

(73) Assignee: Silergy Semiconductor Technology (Hangzhou) LTD, Hangzhou (CN)

(21) Appl. No.: 13/975,485

(22) Filed: Aug. 26, 2013

(30) Foreign Application Priority Data
Oct. 10, 2012 (CN) 201220518856.4

(51) Int. Cl. H01L 23/498

(52) U.S. Cl. CPC H01L 23/49811
USPC 257/762; 257/750; 257/766; 257/778; 257/773

(57) ABSTRACT

Disclosed is a flip chip packaging device and structure of interconnections between a chip and a substrate. In one embodiment, a flip chip packaging device can include: (i) a chip and a substrate; (ii) a plurality of first connecting structures and a plurality of second connecting structures that are aligned and configured to electrically connect the chip and the substrate; and (iii) where each of the plurality of first connecting structures comprises a first metal, and each of the plurality of second connecting structures comprises a second metal, and where a hardness of the first metal is less than a hardness of the second metal.

### RELATED APPLICATIONS

This application claims the benefit of Chinese Patent Application No. 201220518856.4, filed on Oct. 10, 2012, which is incorporated herein by reference in its entirety.

### FIELD OF THE INVENTION

The present invention relates to the field of semiconductor devices, and more particularly to a flip packaging device.

### BACKGROUND

A developing trend in electronic packaging is toward smaller and lighter packages, and flip chip packaging technology is arising in line with this developing trend. As compared to more traditional packaging approaches with lead connections, flip chip packaging technology has advantages of high packaging density, good electric and thermal performance, and high reliability. Conventional flip chip packaging technology can realize electrical and mechanical connections by inverting the chip, and by placing the chip on a substrate or printed-circuit board (PCB) via solder joints.

### SUMMARY

In one embodiment, a flip chip packaging device can include: (i) a chip and a substrate; (ii) a plurality of first connecting structures and a plurality of second connecting structures that are aligned and configured to electrically connect the chip and the substrate; and (iii) where each of the plurality of first connecting structures comprises a first metal, and each of the plurality of second connecting structures comprises a second metal, and where a hardness of the first metal is less than a hardness of the second metal.

Embodiments of the present invention can provide several advantages over conventional approaches, as may become readily apparent from the detailed description of preferred embodiments below.

### BRIEF DESCRIPTION OF THE DRAWINGS

FIG. 1 shows a structure diagram of an example flip chip packaging device.

FIG. 2 shows a structure diagram of an example flip chip packaging device, in accordance with embodiments of the present invention.

FIG. 3 shows a structure diagram of another example flip packaging device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set fourth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

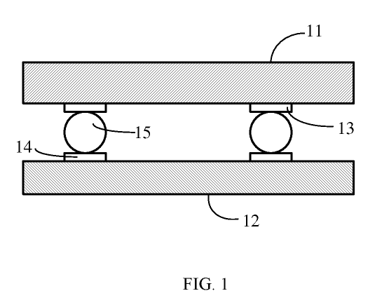

In flip chip packaging, formation of solder joints is an important aspect. Referring now to FIG. 1, shown is a structure diagram of an example flip or flip chip packaging device. This example flip chip structure can include chip 11, substrate 12, chip pads 13, substrate pads 14, and solder balls 15. Chip pads 13 can be placed on an upper surface of chip 11 in order to “lead out” or accommodate an external chip connection, such as to form a chip electrode. A solder ball 15 can be placed between a chip pad 13 and a substrate pad 14 to lead out an electrode of chip 11 through substrate 12.

However, the thermal expansion coefficients of chip 11 and substrate 12 may be different. Thus, when temperature changes, deformation can occur on solder balls 15. Further, such deformation can relate to the height of a solder ball, the chip size, the substrate thickness, and other factors. For example, deformation on solder ball 15 may cause fatigue fracture of the solder ball and in some cases an associated electrical open or short circuit, possibly resulting in system failure.

In particular embodiments, a flip chip packaging device can bear thermal stress resulting from different thermal expansion coefficients of the chip and the substrate, where the thermal stress can result in deformation of a solder ball. A solder ball can effectively be prevented from fatigue fracture, and the thermal stress reliability of the flip packaging device can be improved. Further, by utilizing a group of additional connecting structures with relatively good conductive performance, the chip and the substrate can maintain good electrical conductivity.

In one embodiment, a flip chip packaging device can include: (i) a chip and a substrate; (ii) a plurality of first connecting structures and a plurality of second connecting structures that are aligned and configured to electrically connect the chip and the substrate; and (iii) where each of the plurality of first connecting structures comprises a first metal, and each of the plurality of second connecting structures comprises a second metal, and where a hardness of the first metal is less than a hardness of the second metal.

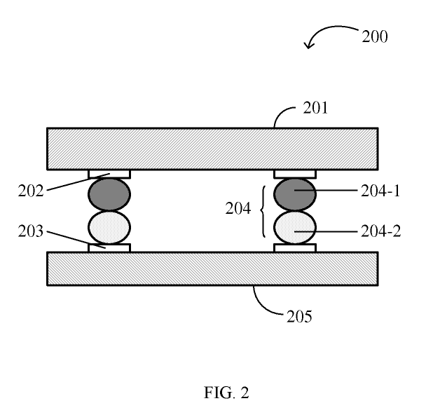

Referring now to FIG. 2, shown is a structure diagram of an example flip packaging device in accordance with embodiments of the present invention. In this particular example, flip packaging device 200 can include chip 201, substrate 205, and a group of connecting devices 204 for connecting chip 201 and substrate 205. For example, connecting devices 204 can include a group of connecting structures 204-1 and a group of connecting structures 204-2. For example, connecting structures 204-1 and/or 204-2 can include solder balls.

Connecting structures 204-1 and connecting structures 204-2 can be mutually spaced, and arranged between chip 201 and substrate 205. As used herein, “mutually spaced” can mean that a position of each connecting structure 204-1 is matched by corresponding position of each connecting structure 204-2. That is, connecting structures 204-1 and 204-2 are in alignment with each other in forming a connection between chip 201 and substrate 205. Specifically, connecting structures 204-1 can be placed above connecting structures 204-2 when chip 201 is flipped for orientation over substrate 205 as shown in FIG. 2.

In addition, connecting structures 204-1 and 204-2 can be formed by, or may include, different materials. For example, connecting structures 204-1 can be formed by a metal (e.g., gold, silver, aluminum, etc.) with a relatively low hardness. In addition, connecting structures 204-2 can be formed by a different metal (e.g., copper, nickel, copper alloy, etc.) with a relatively high hardness. Hardness is a measure of how resistant solid matter is to various kinds of permanent shape change when a force is applied.

When the temperature changes, deformation can occur on connecting devices 204 due to differences between the thermal expansion coefficients of chip 201 and substrate 205. However, since the hardness of connecting structures 204-1 is relatively low, connecting structures 204-1 can bear the thermal stress deformation relatively well through the deformation itself. This can avoid fracture of connecting device 204, which might otherwise result in a circuit open or circuit short condition, thus improving system reliability. In addition, because of the relatively good conductive performance of connecting structures 204-2, the flip packaging device shown in FIG. 2 can provide suitable electrical connectivity between chip 201 and substrate 205.

As shown, connecting devices 204 can be placed on pads 202 of a surface of chip 201. Also, connecting devices 204 can be placed on pads 203 of a surface of substrate 205. Connecting devices 204 can be formed by two superimposed spherical connecting structures 204-1 and connecting structures 204-2. In particular embodiments, connecting structures 204-1 and 204-2 can part of a plurality of mutual spaced connecting structures as shown. Also, connecting structures 204-1 and 204-2 can be formed by, or may include, different types of metal. Further, the positions of connecting structures 204-1 and 204-2 can be exchanged. That is, connecting structures 204-2 (e.g., copper, nickel, etc.) may be placed adjacent to pads 202 at chip 201, and connecting structures 204-1 (e.g., gold, silver, etc.) can be placed adjacent to pads 203 at substrate 205.

Various processes can be utilized to form connecting structures 204-1 and 204-2. For example, spherical shaped connecting structures 204-1 and/or 204-2 can be formed through an ultrasonic welding process, or any other suitable production process. In any event, different materials can be utilized for connecting structures 204-1 versus structures 204-2, including materials having different electrical conductivity characteristics, as well as different hardness factors.

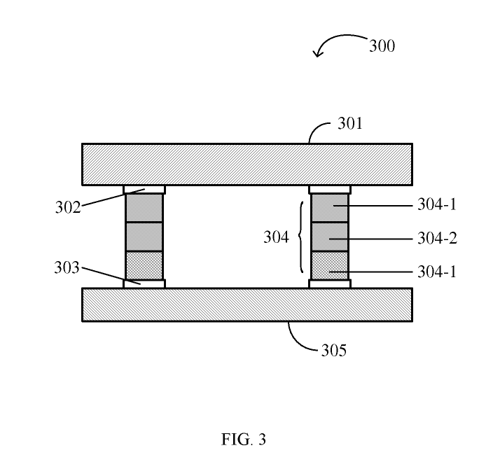

Referring now to FIG. 3, shown is a structure diagram of another example flip packaging device in accordance with embodiments of the present invention. In this particular example, flip packaging device 300 can include chip 301, substrate 305, and connecting devices 304 for connecting chip 301 and substrate 305. In this figure, many structures may be the same or similar to those discussed with respect to FIG. 2, but with a ‘3’ replacing a ‘2’ in leading the element number.

In this example, connecting devices 304 can include two connecting structures 304-1, and one connecting structures 304-2. Connecting structures 304-1 and connecting structures 304-2 can be mutually spaced, and may be arranged between chip 301 and substrate 305. Specifically, connecting structures 304-2 can be placed between two connecting structures 304-1 as shown. Also, connecting structures 304-1 can be formed by a metal (e.g., gold, silver, etc.) with a relatively low hardness.

Further, two connecting structures 304-1 can include the same metal, or a different metal. For example, a top connecting structure 304-1 for connection to pads 302 can include gold, while the bottom connecting structure 304-1 for connection to pads 303 can include silver. Also, connecting structures 304-2 can be formed by a metal (e.g., copper, nickel, etc.) with a relatively high hardness.

When the temperature changes, deformation can occur on connecting devices 304 due to differences in the thermal expansion coefficients of chip 301 and substrate 305. However, since the hardness of connecting structures 304-1 is relatively low, two connecting structures 304-1 can bear the thermal stress deformation relatively well. This can potentially avoid fracture of connecting structures 304 and a circuit open or circuit short condition, thus improving system reliability. Also, because of the relatively good conductive performance of connecting structures 304-2, the flip packaging device shown in FIG. 3 can suitable electrical conductivity between chip 301 and substrate 305.

Specifically, connecting devices 304 can be placed on pads 302 of a surface of chip 301, and on pads 303 of a surface of substrate 305. In this particular example, connecting structures 304-1 and/or 304-2 can be cylindrical in shape. Further, connecting structures 304-1 and/or 304-2 can be formed through any suitable production process, such as an electroplating process.

The embodiments were chosen and described in order to best explain the principles of the invention and its practical applications, to thereby enable others skilled in the art to best utilize the invention and various embodiments with modifications as are suited to the particular use contemplated. It is intended that the scope of the invention be defined by the claims appended hereto and their equivalents.

What is claimed is:

1. A flip chip packaging device, comprising:
a) a chip and a substrate;
b) a plurality of first connecting structures and a plurality of second connecting structures that are aligned and configured to electrically connect said chip and said substrate; and
c) wherein each of said plurality of first connecting structures comprises a first metal, and each of said plurality of second connecting structures comprises a second metal, and wherein a hardness of said first metal is less than a hardness of said second metal.

2. The flip chip packaging device of claim 1, wherein said first metal comprises gold.

3. The flip chip packaging device of claim 1, wherein said first metal comprises silver.

4. The flip chip packaging device of claim 1, wherein said second metal comprises copper.

5. The flip chip packaging device of claim 1, wherein said second metal comprises nickel.

6. The flip chip packaging device of claim 1, wherein each of said plurality of first connecting structures is positioned on a pad of a first surface of said chip.

7. The flip chip packaging device of claim 1, wherein each of said plurality of second connecting structures is positioned on a pad of a first surface of said substrate.

8. The flip chip packaging device of claim 1, wherein each of said plurality of first connecting structures comprises a cylindrical shape.

9. The flip chip packaging device of claim 1, wherein each of said plurality of first connecting structures comprises a spherical shape.

10. The flip chip packaging device of claim 1, wherein each of said plurality of second connecting structures comprises a cylindrical shape.

11. The flip chip packaging device of claim 1, wherein each of said plurality of second connecting structures comprises a spherical shape.
